(19) United States
(12) Patent Application Publication
(10) Pub. No.: US 2007/0075342 A1
(43) Pub. Date: Apr. 5, 2007

(54) Semiconductor device with fin structure and method of manufacturing the same

(75) Inventor: Takahisa Kanemura, Kanagawa (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/527,706

(22) Filed: Sep. 27, 2006

(30) Foreign Application Priority Data
Sep. 30, 2005 (JP) 2005-288217

(51) Int. Cl. H01L 29/76

(52) U.S. Cl. 257/288

(57) ABSTRACT

A semiconductor device with a fin structure according to one embodiment of the present invention includes: a fin of a predetermined height formed on an insulating layer of a substrate; a gate electrode formed on both sides of the fin through a gate insulating film; and a source/drain region formed in the fin on both sides of the gate electrode by implanting impurities into the fin; wherein a concentration of the impurities forming the source/drain region in a vicinity of an interface between the fin and the insulating layer in the fin is lower than a concentration of the impurities in a vicinity of the interface between the fin and the insulating layer in the insulating layer.

### CROSS-REFERENCE TO RELATED APPLICATIONS

This application is based upon and claims the benefit of priority from prior Japanese Patent Application No. 2005-288217, filed Sep. 30, 2005, the entire contents of which are incorporated herein by reference.

### BACKGROUND OF THE INVENTION

The present invention relates to a semiconductor device with a fin structure and a method of fabricating the same.

In order to realize an improvement in a short channel effect, an increase in current driving capability, and a higher degree of integration which are problems or objects in two-dimensionally structured transistors which are the mainstream of the present semiconductor technology, three-dimensionally structured semiconductor devices are under examination. Under such circumstances, with a Fin Field Effect Transistor (FinFET) having a beam-like very thin silicon structure (hereinafter referred to as “a fin”) as a channel, when a fin height is increased, a current can be increased and the high degree of integration can be attained. However, the structure of the FinFET or a method of fabricating the FinFET involves unsolved problems as will be described below.

That is to say, when a source/drain extension region is intended to be formed in processes for fabricating a FinFET device, if impurity ions are implanted into fins from their upper surfaces under the conventional conditions, the extension region having an impurity concentration distribution in a fin height direction is formed. In particular, when the FinFET is fabricated using a usual (100) oriented SOI substrate, the ions cannot reach a sufficiently deep level because they are scattered. For this reason, a region which is short in an interval of extension region is formed in a direction of fin height, a current flows only through this region at the beginning period in operation of a Fin FET, thus, the overall side faces of the FinFET cannot be simultaneously switched. This causes such a problem that the subthreshold characteristics are deteriorated and the current amount is reduced.

On the other hand, when a method of implanting impurity ions in a fin side face direction is adopted for the purpose of avoiding such a structure that the extension region has a distribution in the fin height direction, a limitation of the height and interval of the fins is occurred, and the high degree of integration is impeded.

In addition, when a method of implanting impurity ions using a plurality of implantation energies is adopted, it is also necessary to avoid the transverse spread of the implanted impurity ions in the phase of the implantation of the high energies and the penetration of the implanted impurity ions from a buried oxide film (BOX) to a base substrate. Under such a situation, there has been desired a method of implanting impurity ions in a fin height direction as uniformly as possible with the small transverse spread of the implanted impurity ions in case that impurity ions are implanted in a fin upper surface direction.

### BRIEF SUMMARY OF THE INVENTION

A semiconductor device with a fin structure according to one embodiment of the present invention includes:

a fin of a predetermined height formed on an insulating layer of a substrate;

a gate electrode formed on both sides of the fin through a gate insulating film; and

a source/drain region formed in the fin on both sides of the gate electrode by implanting impurities into the fin;

wherein a concentration of the impurities forming the source/drain region in a vicinity of an interface between the fin and the insulating layer in the fin is lower than a concentration of the impurities in a vicinity of the interface between the fin and the insulating layer in the insulating layer.

A method of fabricating a semiconductor device with a fin structure according to another embodiment of the present invention includes:

forming a fin of a predetermined height on an insulating layer of a substrate;

forming a gate electrode on both sides of the fin through a gate insulating film; and

implanting impurities in a direction substantially vertical to the fin into the fin on both sides of the gate electrode while anneal processing is performed, thereby forming a source/drain region.

### BRIEF DESCRIPTION OF THE DRAWINGS

FIGS. 1A to 1I are respectively cross sectional views showing processes for fabricating a semiconductor device according to an embodiment of the present invention;

FIGS. 2A and 2B are respectively top plan views of the semiconductor device according to the embodiment of the present invention;

FIGS. 3A and 3B are respectively top plan views of the semiconductor device according to the embodiment of the present invention;

FIG. 4 is a side view of the semiconductor device according to the embodiment of the present invention;

FIG. 5 is a graph representing a relationship between a depth of implanted impurity ions and an impurity concentration, of the semiconductor device according to the embodiment of the present invention, which is obtained by performing a simulation; and

FIGS. 6A and 6B are respectively views each showing an impurity concentration distribution and a junction location in a cross section, of the semiconductor device according to the embodiment of the present invention, which is obtained by performing a simulation.

### DETAILED DESCRIPTION OF THE INVENTION

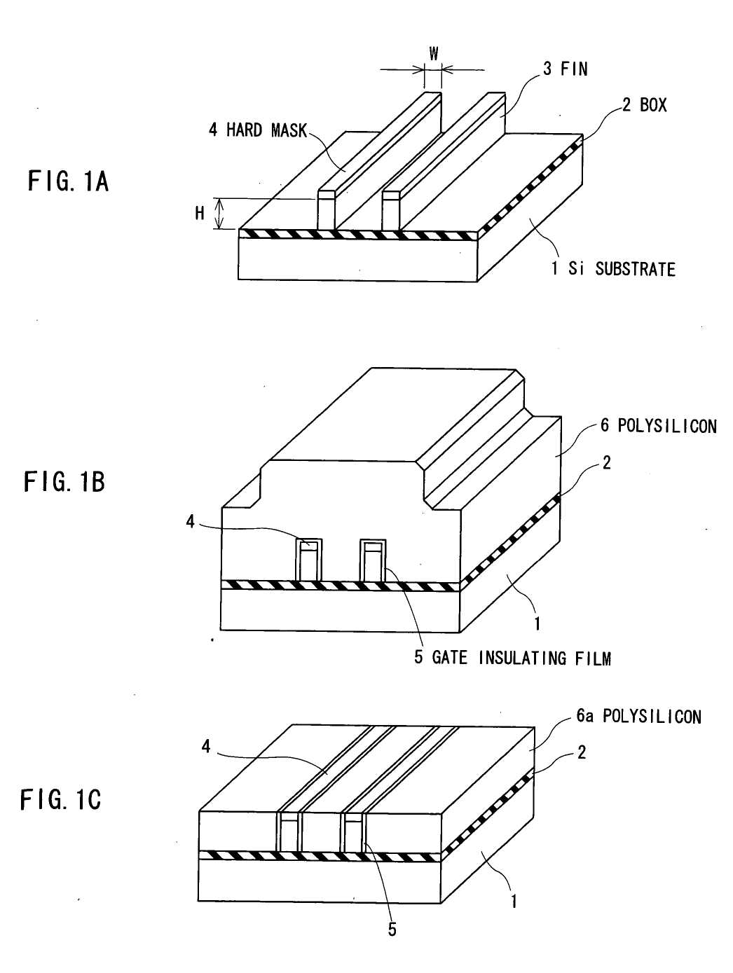

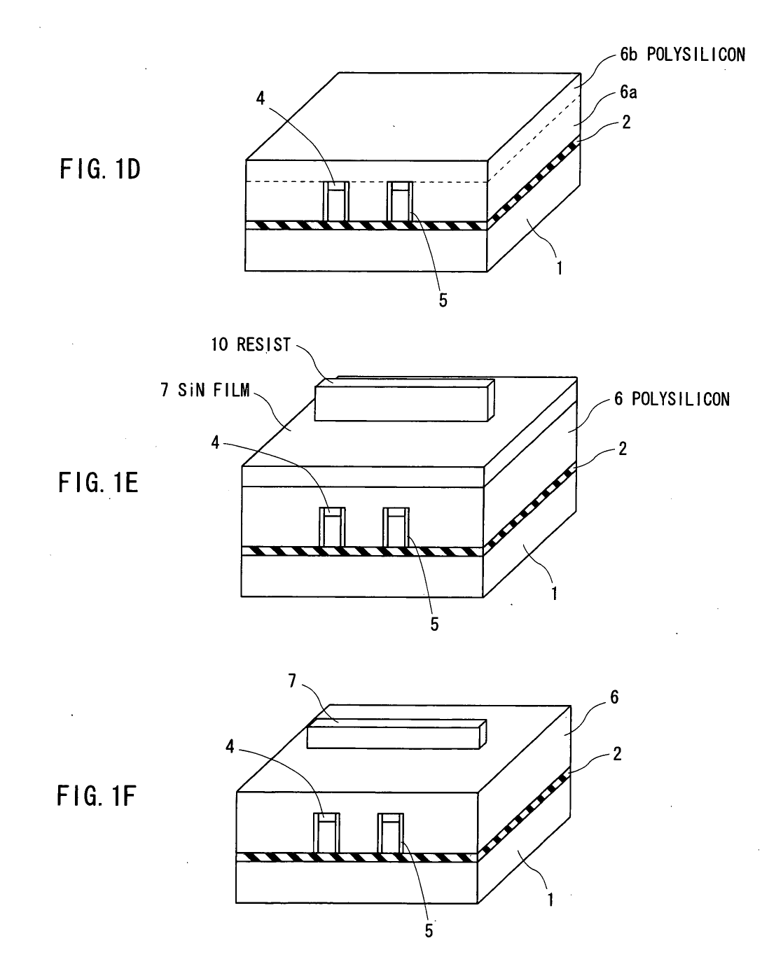

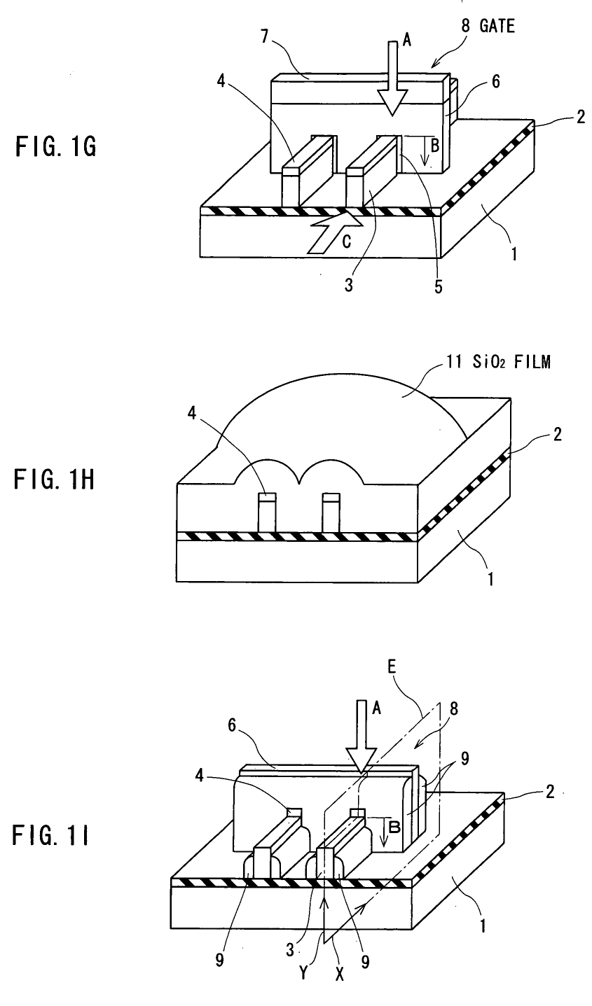

FIGS. 1A to 1I are respectively cross sectional views showing a flow of steps in order for fabricating a FinFET device according to an embodiment of the present invention.

Normally, the FinFET is fabricated using a silicon on insulator (SOI) substrate. In general, a (100) plane is mainly used as a main plane for a Si substrate. However, a (110) plane may be used as a main plane for a Si substrate without any problem. For example, an insulating layer made of a buried oxide (BOX) 2 as a buried oxide film is formed on a silicon substrate 1, and thus the SOI substrate has an SOI layer overlying the BOX 2. After an SiN layer is deposited as a hard mask 4 on the SOI layer, the SiN layer and the SOI layer are selectively etched away with a patterned resist as a mask by utilizing a reactive ion etching (RIE) method or the like, and the patterned resist is then peeled off. FIG. 1A shows a state at this time, and thus two fins 3 as fin type silicon structures are disposed in parallel on the BOX 2. The fin 3 is formed as a single crystal silicon layer which is formed on the BOX 2 by selectively etching away the SOI layer of the SOI substrate. A height, H, of the fin 3 is equal to a thickness of the SOI layer of the SOI substrate. The height, H, of the typical fin is in the range of 50 to 100 nm, and a width, W, thereof is set not to be larger than 20 nm.

FIG. 1B shows a process for depositing polysilicon turning into a gate. After a gate insulating film (made of SiO₂ or the like) 5 is formed through thermal oxidation or the like after completion of the process shown in FIG. 1A, polysilicon 6 is deposited over the whole surface including the fins 3 by utilizing a metal organic chemical vapor deposition (MOCVD) method or the like.

As shown in FIG. 1C, the polysilicon 6 is flattened after completion of the process shown in FIG. 1B. That is to say, the flattening processing is performed with an upper end of the hard mask 4 as a stopper position by utilizing a CMP method.

As shown in FIG. 1D, polysilicon 6b is deposited on polysilicon 6a obtained through the flattening processing and the hard mask 4 by utilizing the MOCVD method or the like after completion of the process shown in FIG. 1C.

As shown in FIG. 1E, an SiN film 7 with a predetermined thickness is deposited on the polysilicon 6 by utilizing the MOCVD method, and a resist 10 for gate formation is formed on the SiN film 7 after completion of the process shown in FIG. 1D.

As shown in FIG. 1F, the SiN film 7 is selectively etched away by utilizing the RIE method or the like after completion of the process shown in FIG. 1E.

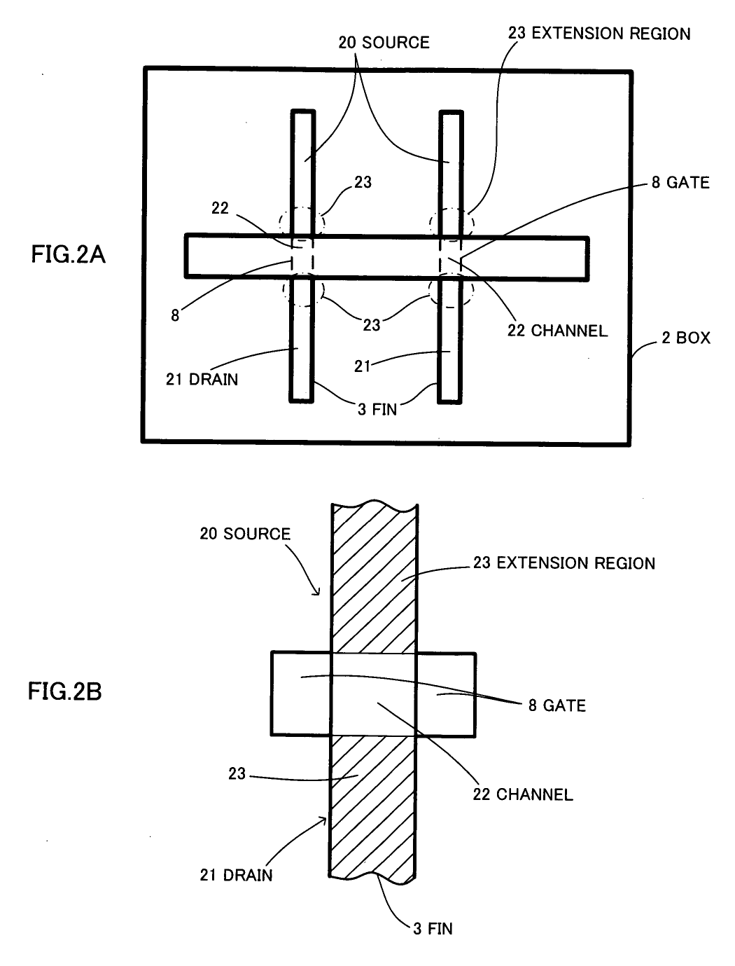

As shown in FIG. 1G, after completion of the process shown in FIG. 1F, the polysilicon 6 is selectively etched away using both the hard mask 4 and the SiN film 7 as a mask by utilizing the RIE method using a fluorine system gas such as CF₄. As a result, a structure having the fins 3 and a gate 8 is formed. Here, FIG. 2A is a top plan view including extension regions 23 when viewed from a direction A in FIG. 1G. Note that, FIG. 2A shows a state after formation of the extension regions 23 of sources 20 and drains 21. In addition, FIG. 2B is an enlarged view showing the vicinity of the gate 8 in FIG. 2A. Impurity ions are implanted into the extension region 23 located in the fin 3 as an electrical connection portion for the source 20, the drain 21 and a channel 22 in the direction A, that is, in a direction substantially vertical to the upper surface of the fin 3. For example, phosphorus ions in the case of an N-channel FinFET and boron ions in the case of a P-channel FinFET can be used as the impurity ions to be implanted. When the impurity ions vertically implanted in the upper surface of the fin 3 whose a plane orientation (100) or (110), the impurity ions reach a deep level in a depth direction B, of the fin 3, shown in FIG. 1G by such a channeling effect that ions pass between crystal lattices, thereby forming a predetermined impurity concentration distribution. In particular, when the plane orientation of the upper surface of the fin 3 is (110), the impurity ions reach the deep level in the depth direction B of the fin 3 all the more because the channeling effect becomes remarkable by implanting vertically the impurity ions, thereby forming nearly the uniform impurity concentration distribution. Here, since the fin 3 is made of a single crystal, the plane orientation of the upper surface of the fin 3 is equal to that of the lower surface (the surface contacting the BOX 2) of the fin 3.

In addition, anneal processing can be performed concurrently with the above-mentioned process for implanting the impurity ions. The anneal processing is performed at a predetermined temperature. Such a temperature that although crystal defects occurring in a course through which the impurity ions pass are repaired, the impurities do not diffuse is preferable as the predetermined temperature.

As shown in FIG. 1H, after completion of the process as shown in FIG. 1G, an SiO₂ film 11 is isotropically deposited by utilizing a CVD method or the like for the purpose of forming a sidewall spacer 9.

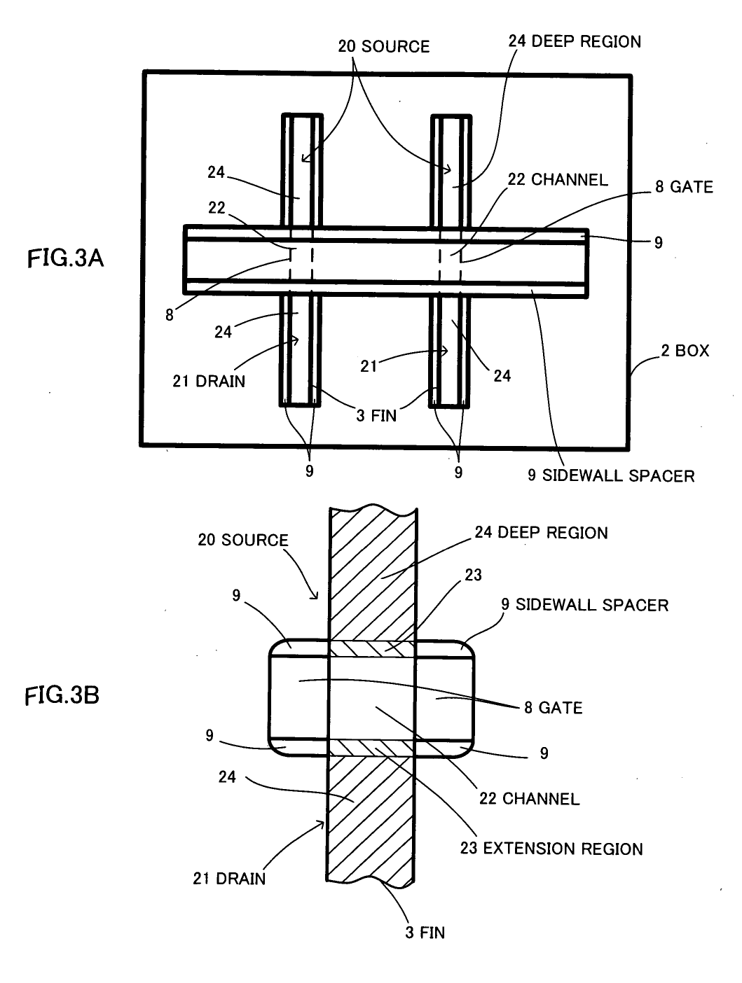

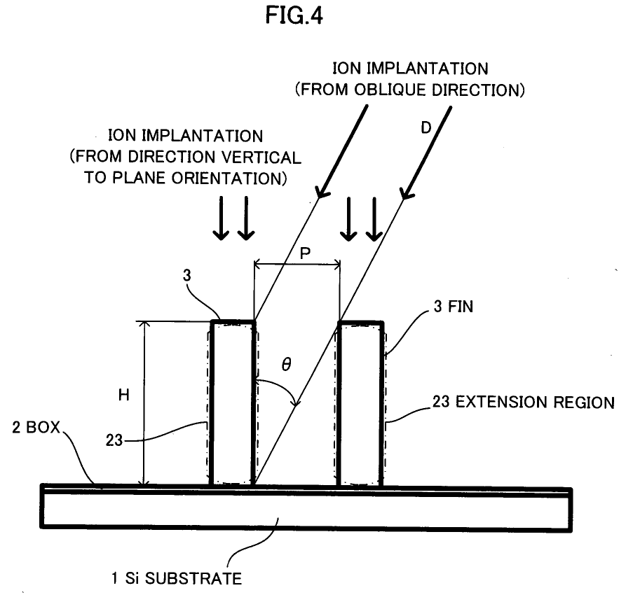

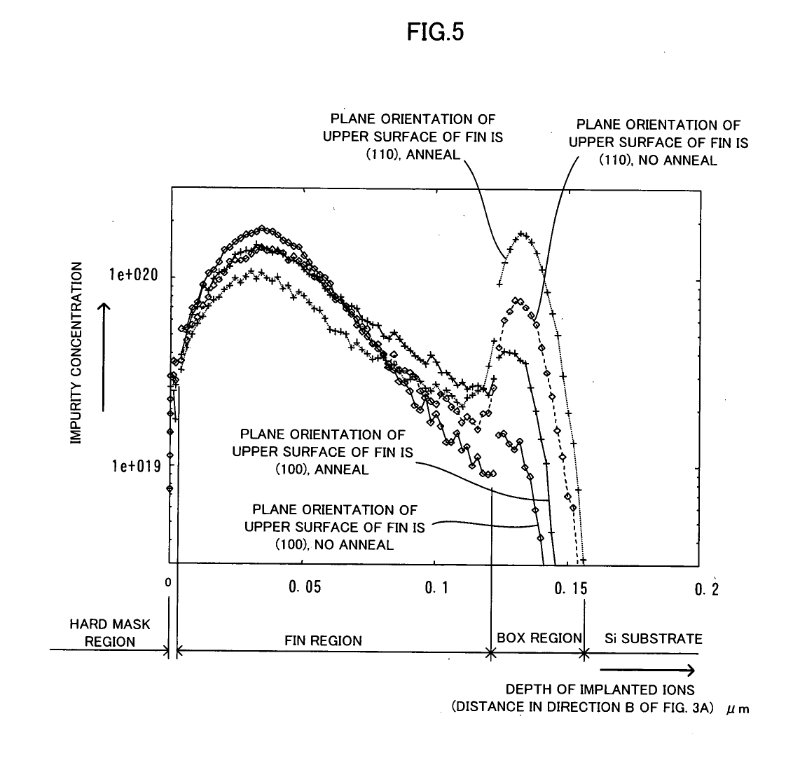

As shown in FIG. 1I, after completion of the process shown in FIG. 1H, the SiO₂ film 11 is removed through etch back by utilizing the RIE method using the fluorine system gas such as CF₄. Here, FIG. 3A is a plan view including deep regions 24 when a structure shown in FIG. 1I is viewed from the direction A in FIG. 1I. Note that, FIG. 3A shows a state after formation of the deep regions 24 of the sources 20 and the drains 21. In addition, FIG. 3B is an enlarged view showing the vicinity of the gate 8 in FIG. 3A. Impurity ions are implanted in the direction A, that is, in the direction vertical to the upper surface of the fin 3 into the deep region 24 for contacting the source 20 and the drain 21. That is to say, the deep region 24 having a high impurity concentration is formed using the sidewall spacer 9 formed on both sides of the gate 8 as a mask edge.

When the impurity ions are implanted in a direction substantially vertical to the upper surface of the fin 3 whose the plane orientation is (100) or (110) similarly to the ion implantation into the extension region 23 shown in FIG. 1G, the impurity ions reach a deep level in the depth direction B, of the fin 3, shown in FIG. 1I by such a channeling effect that the ions pass between the crystal lattices, thereby forming a predetermined impurity concentration distribution. In particular, when the plane orientation of the upper surface of the fin 3 is (110), the impurity ions reach the deep level in the depth direction B of the fin 3 all the more because the channeling effect becomes remarkable by implanting vertically the impurity ions, thereby forming nearly the uniform impurity concentration distribution. In addition, when ions of a light element such as phosphorus or boron are used as the impurity ions to be implanted, the channeling effect becomes more remarkable.

In addition, the anneal processing can be performed concurrently with the above-mentioned process for implanting the impurity ions. The anneal processing is performed at the predetermined temperature. Such a temperature that although crystal defects occurring in a course through which the impurity ions pass are repaired, the impurities do not diffuse is preferable as the predetermined temperature.

FIG. 4 is a side view when the FinFET device is viewed from a direction C in FIG. 1G. A plurality of fins 3 each having a height, H, are formed at an interval, P, on the BOX 2. When the impurity ions are implanted in a side face direction with respect to fin 3 in accordance with the conventional example in order to uniform the impurity. concentration distribution in the height, H, direction in the extension region 23, the impurity ions must be implanted in a direction D shown in FIG. 4, and thus an implantation angle free from an influence by any of other fins 3 must be set. For this reason, if a maximum angle of the oblique ion implantation is θ, when a ratio, H/P, of the height to the interval of a plurality of fins 3 exceeds 1/tan θ and thus the ion implantation into the extension region 23 is blocked off by the adjacent fin 3, it is effective to implant the impurity ions vertically to the upper surface of the fin 3 (in a direction vertical to the plane orientation). In addition, the plane orientation of the upper surface of the fin 3 is preferably (110). Moreover, the anneal processing can be performed concurrently with the above-mentioned process for implanting the impurity ions. The anneal processing is performed at the predetermined temperature. Such a temperature that although crystal defects occurring in a course through which the impurity ions pass are repaired, the impurities do not diffuse is preferable as the predetermined temperature.

Thus, it is also possible to provide a method of fabricating a semiconductor device with a fin structure in which when a maximum angles of the oblique ion implantation by an ion implanter is θ, the ratio, H/P, of the predetermined height to the interval of a plurality of fins exceeds 1/tan θ. In particular, when θ=45°, it is also possible to provide a semiconductor device with a fin structure in which the ratio of the fin height to the interval between the adjacent fins 3 exceed 1.

FIG. 5 is a graph showing an impurity concentration profile, in the FinFET device shown in this embodiment of the present invention, which is obtained by performing a simulation. That is to say, in FIG. 5, the simulation results are plotted with a distance in the direction B from the upper portion of the fin 3 shown in FIG. 1G, that is, an ion implantation depth as abscissa against an impurity concentration as ordinate, and also are plotted for the plane orientation of the upper surface of the fin 3 and the performing of the anneal processing or no anneal processing when the impurity species is boron as parameters.

The concentration of the impurity in the vicinity of an interface between the fin region and the BOX region, for example, in an inner position vertically located at 10 nm from the interface between them is lower in the vicinity of the interface on the fin region side than in the vicinity of the interface on the BOX region side. In particular, a difference in impurity concentration between the vicinity of the interface on the BOX region side and the vicinity of the interface on the fin region side is larger in the impurity concentration distribution when the plane orientation of the upper surface of the fin 3 is (110) than in the impurity concentration distribution when the plane orientation of the upper surface of the fin 3 is (100). For example, the impurity concentration in the inner position of the fin region vertically located at 10 nm from the interface between the fin region and the BOX region is not higher than one third of that in the inner position of the BOX region vertically located at 10 nm from the interface between the fin region and the BOX region. In addition, in the fin region, the impurity concentration distribution when the plane orientation of the upper surface of the fin region 3 is (110) is more uniform than that when the plane orientation of the upper surface of the fin region 3 is (100) irrespective of the anneal processing. In addition, in the case where the plane orientation of the upper surface of the fin 3 is (110), the impurity concentration distribution is more uniform when the anneal processing is performed than that when no anneal processing is performed. This is also applied to the case where the plane orientation of the upper surface of the fin 3 is (100).

In the case where the plane orientation of the upper surface of the fin 3 is (110) and the anneal processing is performed concurrently with the phase of the ion implantation, a ratio of a minimum value to a maximum value of the impurity concentration in the fin height direction is not smaller than ⅕.

A method performing the anneal processing concurrently with the phase of the ion implantation is effective in unifying the impurity concentration distribution because the crystal defects occurring in the course through which the impurity ions pass are repaired. In addition, this method is effective in unifying the impurity concentration distribution irrespective of the plane orientation of the upper surface of the fin 3. In particular, in the case of the high concentration ion implantation, this method is effective in implanting the impurity ions uniformly in the vertical direction since the transverse spread of the implanted impurity ions can be suppressed. Moreover, this method is more effective in implanting the impurity ions into the deep region so that the deep region has a higher impurity concentration than that of the extension region.

The impurity ions can be implanted more uniformly in the vertical direction because the channeling effect is larger and thus the transverse spread of the implanted impurity ions is smaller when the plane orientation of the upper surface of the fin 3 is (110) than when the plane orientation of the upper surface of the fin 3 is (100). In addition, in the former case, the transverse spread of the implanted impurity ions can be made small all the more because the implantation energy can be reduced.

In addition, according to the method of this embodiment of the present invention, the large scale channeling occurs in the region of the fin 3 in the phase of the ion implantation, while no channeling occurs in the BOX 2 underlying the fin 3. That is to say, the concentration of the impurities forming the source/drain region in the fin 3 in the vicinity of the interface between the fin 3 and the BOX 2 as the oxide film is lower than the concentration of the impurities in the vicinity of the interface between the fin 3 and the BOX 2 in the BOX 2. From this fact, as shown in FIG. 5, the impurity concentration in the vicinity of the interface between the fin 3 and the BOX 2 on the BOX 2 region side is higher than that in the vicinity of the interface between the fin 3 and the BOX 2 on the fin 3 side, which results in that it is possible to suppress the reduction in impurity concentration of the fin 3 due to the diffusion of the impurities from the fin 3 side to the BOX 2 side.

In the FinFET device having a plurality of fins formed therein as in one having a Multiple-Fin structure in which a plurality of fins are formed for one gate electrode, when the ratio of the fin height to the fin interval is set not to be smaller than a predetermined value, the extension region and the deep region which have the uniform impurity concentration distributions in the depth direction, respectively, can be formed in accordance with the method of this embodiment of the present invention. In particular, this structure has the large effect in the case where the FinFET devices are integrated with high density.

As described above, according to this embodiment of the present invention, the stable switching operation and the sufficient drive current can be obtained because the uniform impurity concentration distributions are obtained in the extension region and deep region of the FinFET device, respectively. In addition, the semiconductor device with a fin structure and the method of fabricating the same become possible which can cope with the future higher density promotion and higher degree of integration.

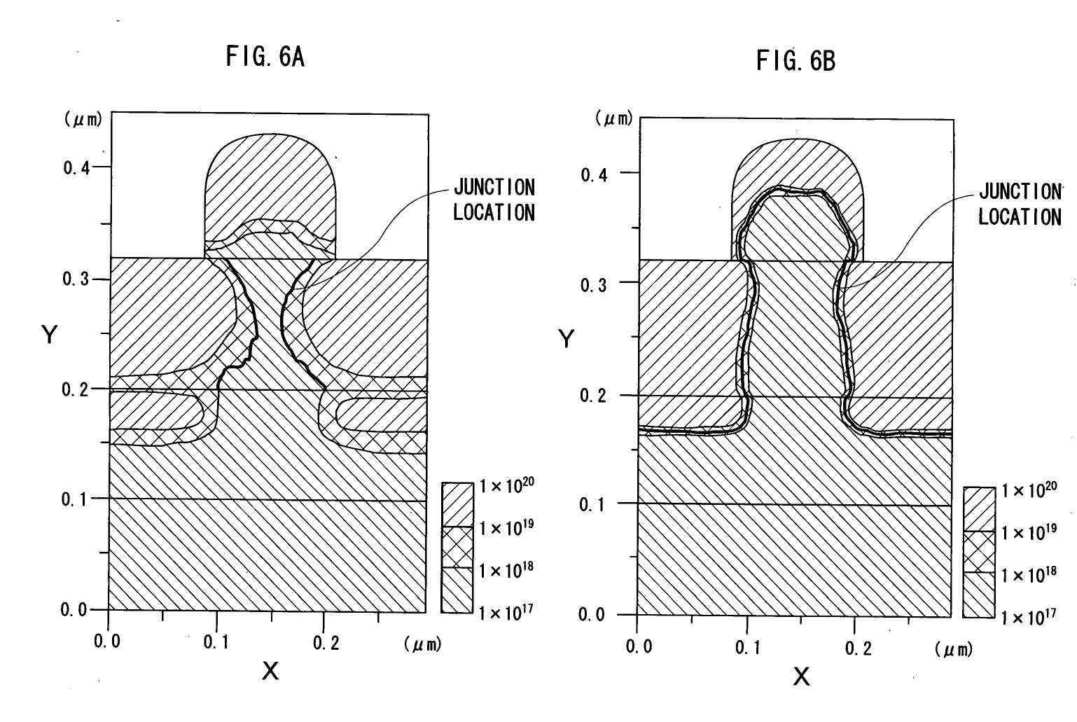

FIGS. 6A and 6B show results of calculating the impurity concentration distributions and junction locations on a cross section E of FIG. 1I. In each of FIGS. 6A and 6B, a region in which a numeric value representing a height in a direction Y is in the range of 0.0 to 0.1 μm is the silicon substrate 1, a region in which the numeric value is in the range of 0.1 to 0.2 μm is the BOX 2, a region in which the numeric value is in the range of 0.2 to 0.32 μm is the fin 3, and a protrusion-like region in which the numeric value is in the range of 0.32 to 0.45 μm is the gate 8 and the sidewall spacer 9 formed on the side faces of the gate 8. FIG. 6A shows the case where the plane orientation of the upper surface of the fin 3 is (100) and no anneal is performed during the ion implantation. In this case, the ion species is phosphorus and the phosphorus ions are implanted vertically to the upper surface of the fin 3 with the implantation energy of 30 keV. The junction location indicated by a heavy line largely changes with respect to the height direction (Y). For this reason, a current begins to be caused to flow through the vicinity of the center in which the interval of the junction locations is narrow in the phase of the device operation. On the other hand, FIG. 6B shows the case where the plane orientation of the upper surface of the fin 3 is (110) and the anneal is performed during the ion implantation in accordance with this embodiment of the present invention to obtain the uniform impurity concentration distribution. Although the ion species is phosphorus similarly to the case of FIG. 6A, the vertical ion implantation may be performed with the implantation energy of 14 keV because the channeling remarkably occurs. The junction location is relatively fixed with respect to the height direction (Y), and thus the current is prevented from beginning to be especially and firstly caused to flow only through the vicinity of the center in the phase of the device operation. In addition, the gate length can be reduced all the more because the spread of the implanted impurity ions in the transverse direction (X) is small. As a result, the scale down is possible.

What is claimed is:

1. A semiconductor device with a fin structure, comprising:
a fin of a predetermined height formed on an insulating layer of a substrate;
a gate electrode formed on both sides of the fin through a gate insulating film; and
a source/drain region formed in the fin on both sides of the gate electrode by implanting impurities into the fin;
wherein a concentration of the impurities forming the source/drain region in a vicinity of an interface between the fin and the insulating layer in the fin is lower than a concentration of the impurities in a vicinity of the interface between the fin and the insulating layer in the insulating layer.

2. A semiconductor device with a fin structure according to claim 1, wherein a plane orientation of a surface of the fin contacting the insulating layer is (110).

3. A semiconductor device with a fin structure according to claim 1, wherein the source/drain region has a concentration distribution of a ratio of a minimum concentration value relative to a maximum concentration value which is not smaller than ⅕.

4. A semiconductor device with a fin structure according to claim 1, wherein the plurality of fins are formed for one gate electrode.

5. A semiconductor device with a fin structure according to claim 4, wherein the plurality of fins are formed so as to have a ratio of a height of each of the fins to an interval between one fin and another fin adjacent thereto that is not smaller than 1.

6. A semiconductor device with a fin structure according to claim 1, wherein the concentration of the impurities forming the source/drain region of an inner position vertically located at 10 nm from the interface between the fin and the insulating layer in the fin is lower than the concentration of the impurities of an inner position vertically located at 10 nm from the interface between the fin and the insulating layer in the insulating layer.

7. A semiconductor device with a fin structure according to claim 2, wherein an inner position vertically located at 10 nm from the interface between the fin and the insulating layer in the fin comprises the concentration of the impurities forming the source/drain region that is not higher than one third of the concentration of the impurities of an inner position vertically located at 10 nm from the interface between the fin and the insulating layer in the insulating layer.

8. A semiconductor device with a fin structure according to claim 1, wherein the fin comprises single crystal silicon.

9. A semiconductor device with a fin structure according to claim 1, wherein the impurities are of at least one of phosphorus and boron.

10. A semiconductor device with a fin structure according to claim 1, wherein the gate electrode comprises polycrystalline silicon.

11. A semiconductor device with a fin structure according to claim 1, wherein the gate insulating film comprises a silicon oxide.

12. A semiconductor device with a fin structure according to claim 1, further comprising a gate sidewall insulating film formed on side faces of the gate electrode.

13. A semiconductor device with a fin structure according to claim 12, wherein the gate sidewall insulating film comprises a silicon oxide.

14. A semiconductor device with a fin structure according to claim 12, wherein the source/drain region comprises the high impurity concentration on both sides of a region in which the gate sidewall insulating film is formed.

15. A method of fabricating a semiconductor device with a fin structure, comprising:
forming a fin of a predetermined height on an insulating layer of a substrate;
forming a gate electrode on both sides of the fin through a gate insulating film; and
implanting impurities in a direction substantially vertical to the fin into the fin on both sides of the gate electrode while anneal processing is performed, thereby forming a source/drain region.

16. A method of fabricating a semiconductor device with a fin structure according to claim 15, wherein the fin is formed so that a plane orientation of a surface of the fin contacting the insulating layer is (110).

17. A method of fabricating a semiconductor device with a fin structure according to claim 15, wherein the impurities are of at least one of phosphorus and boron.

18. A method of fabricating a semiconductor device with a fin structure according to claim 15, wherein the plurality of fins are formed for one gate electrode.

19. A method of fabricating a semiconductor device with a fin structure according to claim 18, wherein the plurality of fins are formed so as to have a ratio of a height of each of the fins to an interval between one fin and another fin adjacent thereto that is not smaller than 1.

20. A method of fabricating a semiconductor device with a fin structure according to claim 15, further comprising:
forming a gate sidewall insulating film on side faces of the gate electrode after the source/drain region is formed; and
further implanting impurities in a direction substantially vertical to the fin into the source/drain region while anneal processing is performed using the gate electrode and the gate sidewall insulating film as a mask.
